(19) United States
(12) Patent Application Publication
(10) Pub. No.: US 2025/0216767 A1
(43) Pub. Date: Jul. 3, 2025

(54) METHODOLOGY FOR PATTERNING ACROSS FIELDS USING CLEAR FIELD MASKS AND NEGATIVE TONE RESISTS

(71) Applicant: Intel Corporation, Santa Clara, CA (US)

(72) Inventors: Thomas Broiles, Hillsboro, OR (US); Sunjeev Venkateswaran, Springfield, MO (US); Kimberly Pierce, Beaverton, OR (US); Dhananjay Bhawe, Hillsboro, OR (US)

(73) Assignee: Intel Corporation, Santa Clara, CA (US)

(21) Appl. No.: 18/400,696

(22) Filed: Dec. 29, 2023

(51) Int. Cl. G03F 1/42; H01L 21/768

(52) U.S. Cl. CPC G03F 1/42; H01L 21/768

(57) ABSTRACT

An integrated circuit (IC) device may include features that were patterned using overlapping exposure fields and that span the region of overlap between the exposure fields. The features may be developed from negative tone photoresist exposed using one or more clear-field reticles. A clear-field reticle may include a reflective substrate and absorber features in an opaque mask on the substrate. A single reticle may have complementary portions of an overlapping pattern, e.g., for a line feature, on opposite edges. Complementary portions of an overlapping pattern may be on different reticles.

### BACKGROUND

Demand for increasingly complex integrated circuit (IC) devices is spurring investigation into more and different solutions for stitching together circuits patterned from separate photolithography exposures. Combining multiple exposures provides design flexibility, for example, to form IC dies of greater size than standard photolithography fields or to employ smaller-than-standard, higher-resolution exposures. However, fabricating robust interconnections of fine features spanning exposure fields introduces manufacturing difficulties. For example, minor overlay misalignments can cause significant interconnect thinning or even discontinuities. A limited quantity of solutions, e.g., using only positive tone photoresist and dark-field exposures, have been presented to develop robust power and/or signal interconnections between separately exposed circuit blocks.

New techniques and structures are needed to provide further flexibility, to enable the use of alternative materials not previously used in reticle stitching applications, and to form improved interconnections between separate photolithography exposures.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIGS. 1A, 1B, and 1C illustrate an example monolithic die including line features fabricated by clear-field reticle stitching using overlapping line end features, in accordance with some embodiments;

FIG. 2 illustrates an example lithographic patterning context for deploying reticle stitching using overlapping line end features, in accordance with some embodiments;

FIGS. 3A, 3B, 3C, and 3D illustrate example line features generated by overlapping first and second pattern portions deploying line end features having symmetric stair-step patterns, in accordance with some embodiments;

FIGS. 4A and 4B illustrate example line features generated by overlapping first and second portions deploying tapering features or regions, in accordance with some embodiments;

FIGS. 5A and 5B illustrate example line features generated by overlaying first and second pattern portions having shared regions adjoining multiple individual continuous regions, in accordance with some embodiments;

FIG. 6 is a flow diagram illustrating an example process for fabricating an integrated circuit device, in accordance with some embodiments;

FIGS. 7A, 7B, 7C, 7D, and 7E are views of example integrated circuit (IC) device structures as particular fabrication operations are performed, in accordance with some embodiments;

FIG. 8 illustrates a diagram of an example data server machine employing an IC device having line features between overlapping reticle exposures, in accordance with some embodiments; and

FIG. 9 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicate that two or more elements are in either direct or indirect (with other intervening elements between them) physical or electrical contact with each other, and/or that the two or more elements co-operate or interact with each other (e.g., as in a cause-and-effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Photolithography techniques, reticle features, and devices are described herein related to improving overlay margins for lines that span reticle boundaries in reticle stitching applications and to enabling the use of materials key to certain high-resolution tooling.

Recent developments in the integrated circuit (IC) industry have created a need to pattern features, such as interconnect metals, that span across adjacent lithographic fields, e.g., to manufacture components which are larger or smaller than standard reticle field sizes. For example, at least some high-NA (numerical aperture), EUV (extreme ultraviolet) lithography will combine exposures in an IC die to include a field size half of the typical field size. Such combining (i.e., stitching together) of reticle fields may also be utilized to manufacture products exceeding even the largest exposure field, e.g., to generate up to wafer-sized die. Such overlapping of lithographic patterns to generate continuous features must account for the photolithography process used (e.g., clear field (CF) or dark field (DF)), as well as the tone of the photoresist (e.g., positive tone develop (PTD) or negative tone develop (NTD)). The present disclosure describes an overlay insensitive approach for patterning with NTD resists and CF mask processes. Such robustness to overlay issues (including registration and distortion errors) between stitched reticle fields results in less critical dimension (CD) variation and fewer failures, and so increases fab yields and process reliability. Such features and techniques also prevent significant thinning or bulging (e.g., laterally in a plan view) of the metal lines at the overlay interface, resulting in improved resistance characteristics of the signal lines (e.g., avoidance of increased resistance due to thinning), including reduced resistance variation.

In deploying a CF lithographic process where light exposure hardens (e.g., polymerizes) NTD photoresist, multiple reticle fields must be protected from inadvertent light exposure into dark regions, which may result in a blocked interconnect. Rather than precisely aligning feature edges or diffusing photoacids (as in a PTD, DF solution), the present description utilizes extra masking to enable a more overlay insensitive solution. Such an NTD, CF lithographic process provides robustness to overlay errors between the two exposures by widening interconnect patterns, which may counter polygon shrinkage that may otherwise be caused by the increased light from an extra exposure.

The proposed solution also advantageously enables the employment of tools (such as certain high-NA systems) and materials (such as NTD resist) which are of particular interest for the tightest metal interconnects and via layers. NTD resist may also be deployed for patterning lower-resolution features, such as metal interconnects in higher layers. NTD resist may beneficially enable faster photolithography speeds, provide wider process latitudes (e.g., better adhesion capabilities to certain substrate materials), and significantly lower operating costs.

Notably, patterning features or polygons using NTD resist and a CF lithographic process differs from typical PTD, DF processing. Developing features using photolithography involves coating a wafer with a photosensitive resist, which is typically sensitive to light of a certain wavelength. Such light may be in the visible spectrum, but also includes UV wavelengths, etc. The light of this wavelength is then shone through a mask that contains the desired pattern to be transferred to the wafer. Herein, patterns, regions, features and the like are discussed with respect to reticle mask patterns and resultant patterns on the photoresist interchangeably. It is noted that the pattern at the resist level is typically reduced (e.g., by 4×) from the reticle mask level and is invariably an imperfect reproduction. Herein, the discussed patterns, regions, or features may be at the reticle level (i.e., in the reticle mask) or at the resist level (e.g., either pre- or post-development). Negative (or NTD) photoresist becomes insoluble (or less soluble, e.g., polymerizes) upon exposure to light, and so the photoresist developer dissolves and removes unexposed NTD resist, but retains exposed NTD resist. (This differs from a positive (or PTD) resist where the region of photoresist on the wafer that is exposed to the light generates photoacids that break down the resist polymer making it soluble in a developer solution.) In a CF (or bright field) lithographic process using NTD resist, the reticle masks eventual features to be developed (such as a line feature or other polygon) and exposes adjacent regions to light, for example, to remove resist in a trench (e.g., to form the line feature) between retained resist on both sides of the trench. In reticle stitching contexts, a feature such as a line feature is generated by two different masks (or different regions of the same mask) exposed sequentially such that a portion of the line feature from the first exposure and a portion of the line feature from the second exposure are adjoined at the stitch. As used herein, the term adjoin indicates two features, portions, or regions are in contact with one another. When using NTD, CF processing, reticles must be thoughtfully designed to overlap and not unintentionally harden resist in the feature or overexpose resist next to the feature. Overexposure of resist regions adjacent the feature might provide light energy beyond a feature border over a critical value to polymerize resist such that regions of insoluble resist may encroach on or shrink the feature (e.g., trench).

Since each exposure has a certain placement error and/or distortion error, the combined placement error and/or distortion error of the two exposures might typically result in a gap, an overlap, or both in the overlapping exposure regions. Reticles for NTD, CF processing may be designed with extra masking to preclude a gap and to intentionally overlap mask portions meant to not be exposed. A reticle with extra masking away from a feature results in no extra feature development if the region is in the clear, bright field of the other exposure. Excessive light exposure hardens too much resist (narrowing a trench feature), and insufficient light exposure hardens too little resist (widening a trench feature), but flared feature patterns at the overlapped regions can ensure that registration mismatch and/or distortion error between the two exposures result in only minimal narrowing or bulging of line features.

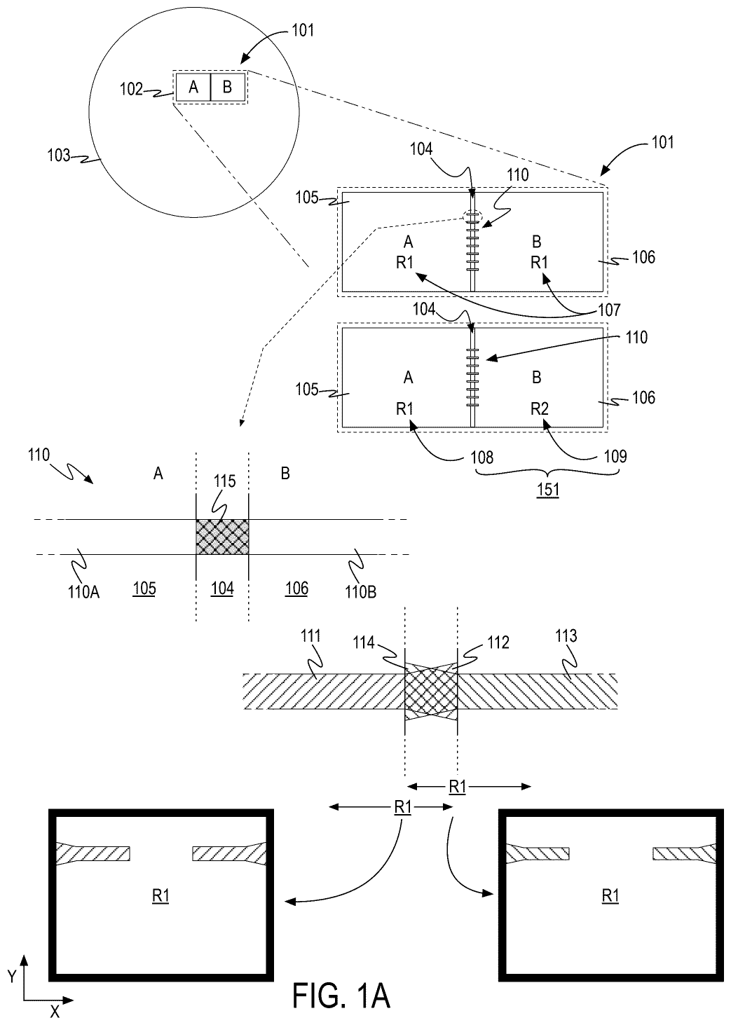

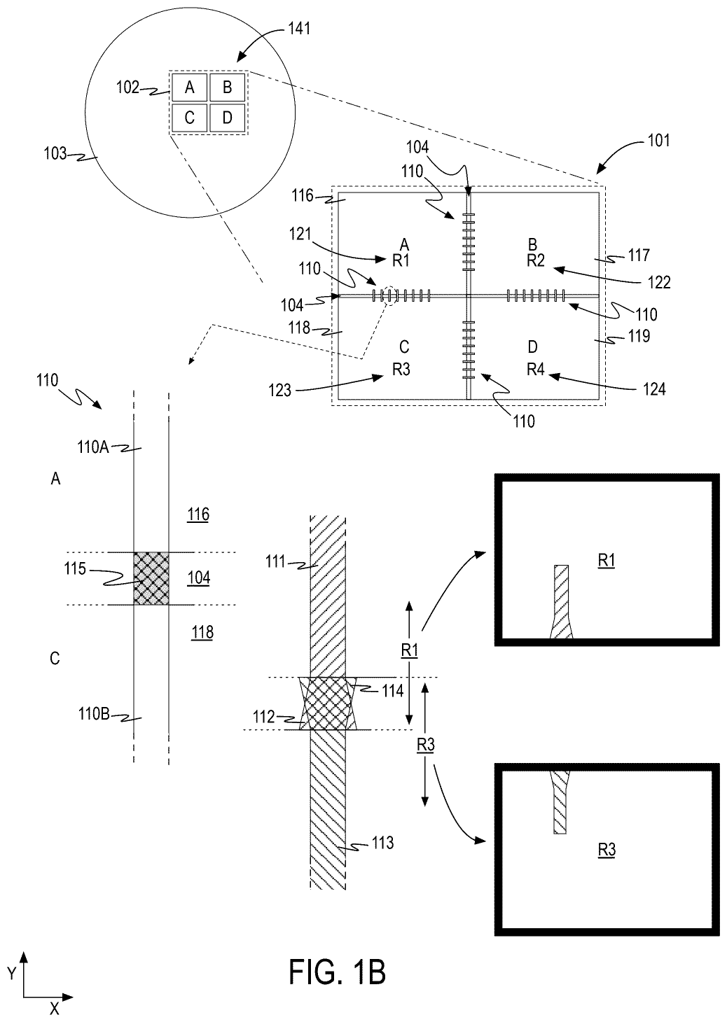

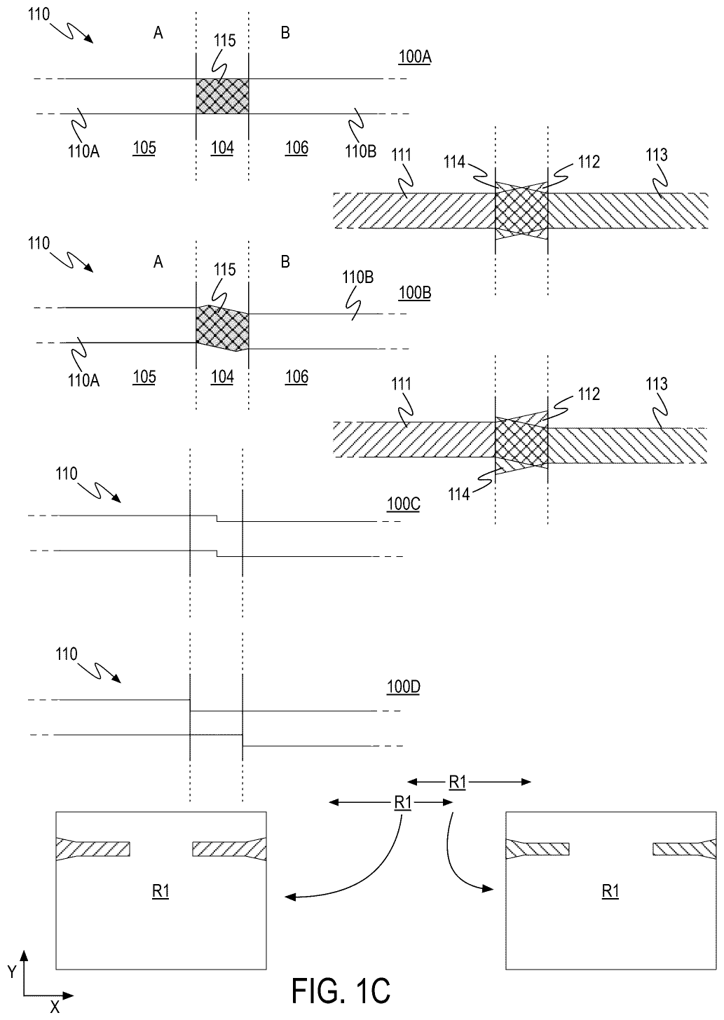

FIG. 1A illustrates an example monolithic die 101 including line features fabricated by clear-field reticle stitching using overlapping line end features, in accordance with some embodiments. As shown, die 101 may be singulated from substrate wafer 103 using scribe cuts 102 that surround die 101 but do not cut through or between fields 105, 106 (also labeled as A and B) of die 101 such that fields 105, 106 correspond to areas or regions patterned using separate lithography exposures. The separate lithography exposures may be (e.g., temporally) distinct, but intersect at a small area 104 of overlap. Fields 105, 106 may also be characterized as regions. Fields 105, 106 are patterned in separate lithography exposures that may include reticle stitched features or line features 110 (e.g., line features or metal signal lines) that are to be connected across an overlapping region of fields 105, 106. As used herein, the term reticle stitched feature or line indicates a feature or line that crosses over between reticles and exposure fields such that one portion or region is from a first reticle and exposure field and a second portion or regions from a second reticle and exposure field.

A portion of each of line features 110 corresponds to a continuous portion or region 111 from exposure of field 105 and a continuous portion or region 113 from exposure of field 106. The terms portion and region are used interchangeably herein. The term continuous with respect to a region or portion indicates the region or portion is uninterrupted. A continuous region having a width across a particular length indicates the region is uninterrupted in the area defined by the width and length. Line feature 110A is the portion of line feature 110 corresponding to continuous region 111, and line feature 110B is the portion of line feature 110 corresponding to continuous region 113. Line features 110A, 110B may extend and continue away from merged region 115 (and regions 111, 113 away from regions 112, 114) as indicated in at least some figures by dashed borders out in both x-directions.

As shown, each of line features 110 includes a merged portion or region 115 that is defined by the cumulative exposure of field 105 and exposure of field 106, rather than by either of the exposures independently. As used herein, the term merged portion or region indicates a resultant region of the overlay of patterns of two regions. Merged portion or region 115 corresponds to the intersection of overlapping portions or regions 112, 114. An intersection of overlapping regions 112, 114 is that area covered by both regions, i.e., the overlapped area. The width of line feature 110 may vary (e.g., narrow or bulge) slightly at merged region 115 depending on the interaction between, e.g., the extra exposure to light of resist adjacent regions 111, 112, 113, 114 and the flared pattern widths of regions 112, 114. As described, photoresist next to a (e.g., trench) feature may cause feature shrink if overexposed. Advantageously, the flared widths of regions 112, 114 counteract or balance out the effect of the extra exposure adjacent merged region 115.

End line region patterns used to provide merged region 115 in a robust manner are discussed further herein. Such end line region patterns are provided in reticle patterns and transferred to a photoresist layer on or over substrate wafer 103. Such overlapping end line regions may be patterned using different reticles for each of fields 105, 106 or the same reticle for both of fields 105, 106. In examples where the same reticle is used, a same reticle 107 (R1) is used to pattern both fields 105, 106. In such examples, the pattern of line feature 110A and merged region 115 from the exposure of field 105 includes regions 111, 112 at a first edge of reticle 107 (e.g., to pattern a right side of field 105) and the pattern of line feature 110A and merged region 115 from the exposure of field 106 includes regions 113, 114 at an opposite edge of reticle 107 (e.g., to pattern a left side of field 105).

In examples where different reticles are used, the same relationship of the features is provided using different reticles 108 (R1), 109 (R2). For example, region 111 and the pattern of merged region 115 from the exposure of field 105 is at a first edge of reticle 108 (e.g., to pattern a right side of field 105) and region 113 and the pattern of merged region 115 from the exposure of field 106 is at an opposite edge of reticle 109 (e.g., to pattern a left side of field 105). As shown, reticles 108, 109 may be part of a reticle set 151 that are used to pattern dies 101. Such multi-reticle applications provide greater flexibility in patterning the features of dies 101.

Though not shown in all figures, reticles R1 (etc.) may include an opaque border around any included pattern to ensure reticle exposure is precisely delineated at edges of the reticle and pattern(s), as shown in FIG. 1A. For example, a border of and around reticle R1 may ensure that the eventual trench of line features 110A, 110B is not exposed beyond an intersection of regions 112, 114 and across regions 111, 113. Such exposure would potentially harden resist, bridging resist across the trench and causing a gap in line features 110A, 110B.

FIG. 1B illustrates an example monolithic die 141 including line features fabricated by clear-field reticle stitching using overlapping line end features, in accordance with some embodiments. As shown in FIG. 1B, line features 110 may be fabricated across reticle boundaries between any number of reticles and corresponding fields 116, 117, 118, 119. For example, using reticle stitching techniques, fields 116, 117, 118, 119 may scale to stitch an entire wafer or large portions (e.g., a half, a third, or a quarter) of a wafer. In the example of FIG. 1B, four reticles 121 (R1), 122 (R2), 123 (R3), 124 (R4), are deployed but any number may be used. Furthermore, FIG. 1B illustrates line features 110 may extend in any direction between fields 116, 117, 118, 119.

Though not illustrated in subsequent figures, all reticles R1, R3 (etc.) may deploy an opaque border around any included pattern to ensure reticle exposure is precisely delineated at edges of the reticle and pattern(s), as shown in FIG. 1B. For example, a border of and around reticle R3 may ensure that the eventual trench of line feature 110A is not exposed beyond an end of region 114 away from region 113. Such exposure would potentially harden resist, bridging resist across the trench and causing a gap in line feature 110A.

FIG. 1C illustrates an example monolithic die including line features 110 fabricated by clear-field reticle stitching using overlapping line end features, in accordance with some embodiments. FIG. 1C shows views 100A, 100B, 100C, and 100D of line features 110 with and without registration errors of reticle R1, and with and without flared overlapping regions 112, 114.

View 100A shows line feature 110 generated without a registration error from regions 111, 113 and overlapping regions 112, 114, much as described at FIG. 1A. Note that line feature 110 is continuous along features 110A, 110B and merged region 115. Note also that, as described at least at FIG. 1A, the width of line feature 110 may vary (e.g., narrow or bulge) slightly at merged region 115 depending on the interaction between, e.g., the extra exposure to light of resist adjacent regions 111, 112, 113, 114 and the flared pattern widths of regions 112, 114. These factors have interacted such that features 110A, 110B and merged region 115 are continuous, e.g., due to proper design of the patter flares for a given exposure intensity, etc. View 100B shows line feature 110 generated with a registration error in the y-direction from regions 111, 113 and overlapping regions 112, 114. Note again that, while merged region 115 shows as bulging slightly, width of line feature 110 may vary (e.g., narrow or bulge) slightly at merged region 115 depending on, e.g., extra light exposure and pattern flares, and (given the same conditions described at view 100A) merged region 115 might actually narrow slightly with the misregistered exposures. However, line feature 110 was generated fairly robustly given the registration error.

Views 100C, 100D show examples of severely narrowed line features 110 due to the misregistration error and a lack of pattern flaring and/or overlapping. View 100C shows a narrowed line feature 110 as no flaring provides any means of compensating for the misregistration. Note that the generated line feature 110 is a best-case result with no overlapping regions (and perfectly abutting exposures) and assumes no misregistration in the x-direction. Even a slight misregistration could cause a (double-exposed) gap in the printed line feature 110. View 100D shows a narrowed line feature 110 with overlap but without flaring. The overlapping exposures cause a longer length of the narrowed region due to the lack of any pattern flare. Views 100C, 100D show examples of line features 110 lacking the benefits of the overlapping flared patterns of view 100B.

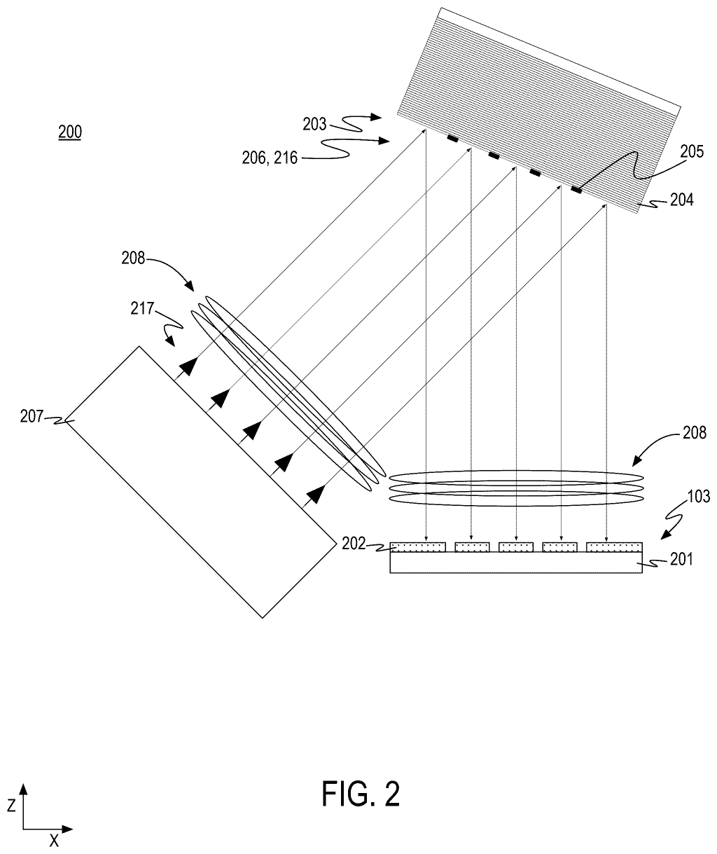

FIG. 2 illustrates an example lithographic patterning context 200 for deploying reticle stitching using overlapping line end features, in accordance with some embodiments. In FIG. 2, a light source 207 is used to provide an exposure 217 using a reticle 203. Reticle 203 includes a reflective substrate 204 and a substantially opaque mask 205 providing a pattern 206 or 216 on a reflective substrate 204. For example, depending on the reticle 203 being deployed any pattern 206, 216, etc., discussed herein may be used.

In the example of FIG. 2, reflective substrate 204 includes a multilayer Bragg reflector having alternating layers of differing composition (e.g., silicon and molybdenum), which may be well-suited to certain EUV applications and equipment. Opaque mask 205 and patterns 206 or 216 include absorber features, which do not reflect light and which make patterns 206 or 216 opaque to exposure 217 of light from source 207. In some embodiments, absorber features include tantalum, which may be well-suited to certain (e.g., EUV) wavelengths. Although the implementation and employment of the described methods and devices, etc., may benefit EUV applications, the principles, methods, devices, etc., described are not limited to EUV contexts. Other materials and structures may be deployed, such as transparent clear-field reticles 203 and substrates 204, including reticles 203 and substrates 204 optimized for UV, deep UV (DUV), etc., wavelengths. Clear-field reticles 203 and substrates 204 may beneficially enable the use of phase-shift masks to ensure proper line widths. Although masks and patterns may be described as opaque, in some embodiments, such descriptions include phase-shift masks, which may combine opaque elements with phase shifting.

Exposure 217 continues from reticle 203 through optics 208 to expose a photoresist layer 202 on or over a substrate 201 (e.g., a substrate wafer). As discussed, the resultant exposure may polymerize portions of photoresist layer 202, rendering it insoluble in a developer solution, such that exposed photoresist is retained while unexposed, soluble resist is removed. As discussed, pattern 206 or 216 is transferred from reticle 203 to photoresist layer 202. The pattern features, regions, etc., discussed herein are applicable to either or both of pattern 206 or 216 of reticle 203 and the resultant pattern of photoresist layer 202.

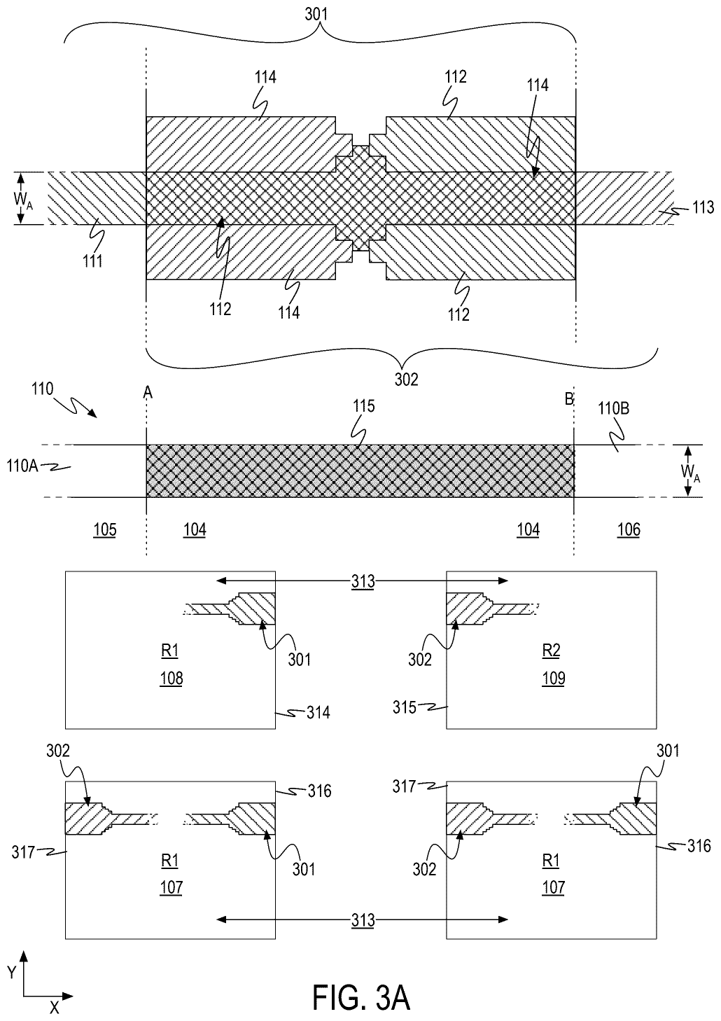

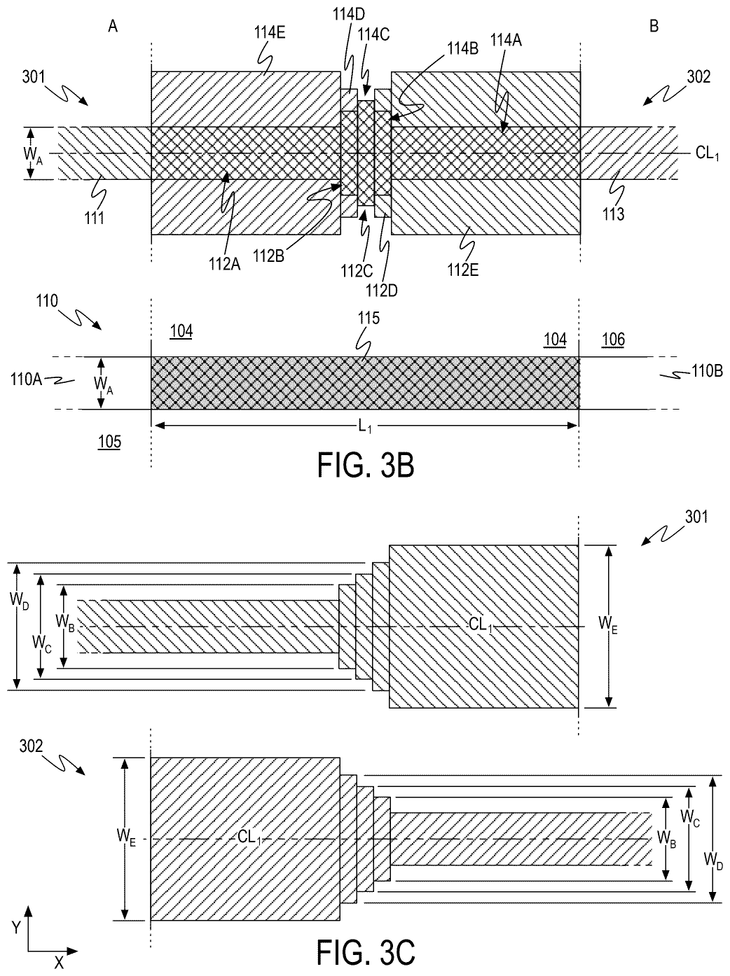

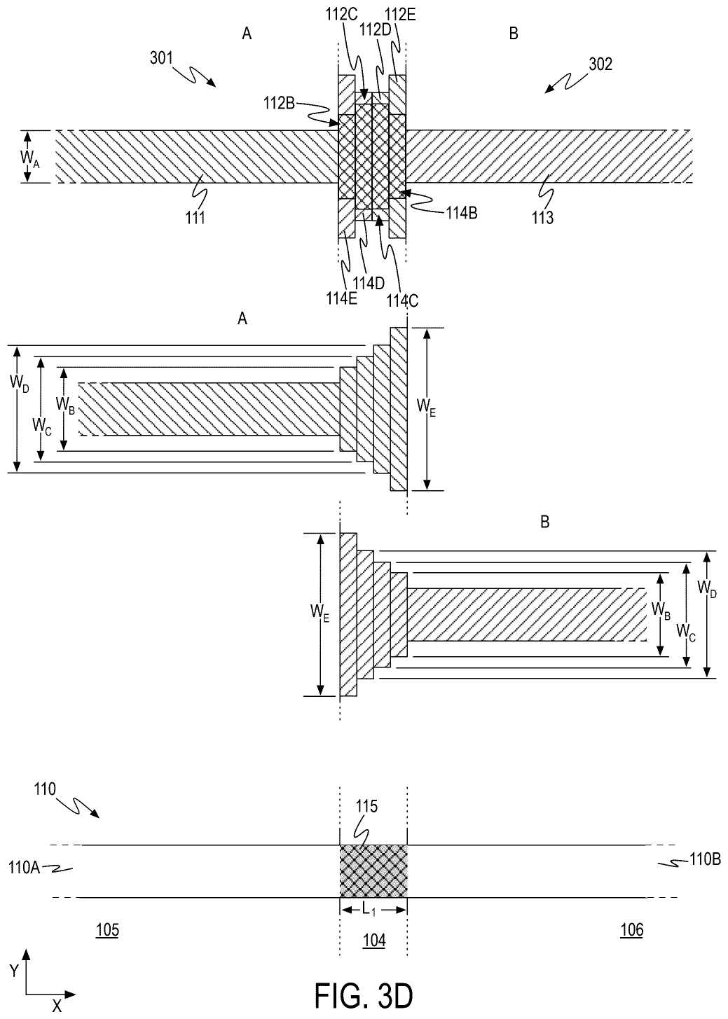

FIGS. 3A, 3B, 3C, and 3D illustrate example line features 110 generated by overlapping first and second pattern portions 301, 302 deploying line end features having symmetric stair-step patterns, in accordance with some embodiments. As shown in FIG. 3A, line feature 110 is fabricated by overlapping a first portion 301 from a first reticle R1 and corresponding exposure and a second portion 302 from a second exposure using the first reticle R1 or a second reticle R2. (FIG. 3B shows portions 301, 302 offset, not overlapped, e.g., for illustrative purposes.) First portion 301 includes a first continuous feature or region 111 that has a width w_{A} along a length (in the x-dimension) thereof. As used herein, the term width provides a dimension taken across a line feature such that a length of the line feature extends in a long dimension and the width is orthogonal to the long dimension. Herein, line features are typically illustrated extending along a length in the x-dimension such that widths are commonly taken in the y-dimension. Although illustrated as straight lines, such lines may have jogs, changes in direction, etc., particularly moving away from the merged region. At the wafer level, line feature 110 (and other line features discussed herein) may be at any level of a back end of line (BEOL) metallization stack. In some embodiments, line feature 110 (and other line features discussed herein) are deployed at metal 7 (M7) and/or higher. In some embodiments, line feature 110 (and other line features discussed herein) are at lower metallization levels such as M4, M5, M6 and higher. In some embodiments, line feature 110 (and other features discussed herein) are at lower metallization levels, such as M0, M1, etc., e.g., coupling with a device layer.

As shown, continuous region 111 is an uninterrupted region in an area defined by width w_{A} and the length of continuous region 111, which may extend in the x-dimension. Adjoining continuous region 111 is a region 112 of first portion 301. As shown, region 112 of first portion 301 has a symmetric stair-step pattern such that widths of features of region 112 increase moving away from region 111, as discussed further herein below.

Similarly, second portion 302 of line feature 110 includes a first continuous feature or region 113 that has a width w_{A} along a length (in the x-dimension) thereof. Continuous region 113 is an uninterrupted region in an area defined by width w_{A} and the length of continuous region 113 and is adjoined by a region 114 of second portion 302. As shown, region 114 of second portion 302 has an inverse stair-step pattern relative to the stair-step pattern of region 112 such that widths of features of region 114 increase moving away from region 113. Furthermore, the pattern of region 114 is the inverse of the pattern of region 112 such that they both flare to larger widths away from their respective continuous regions and away from a narrower central region of overlap. For example, regions 112, 114 have larger widths away from the respective continuous regions 111, 113 (and away from the narrower central regions of overlap) overlapping much narrower widths of the other regions 114, 112, respectively, where the other regions 114, 112 are adjacent their respective continuous regions 113, 111, respectively. As used herein, the term inverse patterns indicates a pattern that is the opposite or complementary, such as a reflection about an axis perpendicular to a shared centerline of continuous regions 111, 113. Such an axis of reflection may be internal to a region, as in the examples of regions 112, 114 in FIG. 3A.

Merged region 115 is formed from or provided by the intersection of overlapped regions 112, 114. Region 112 may be significantly wider than region 114 adjacent region 113 (and region 114 may be significantly wider than region 112 adjacent region 111), which may ensure no extra exposure of resist adjacent the narrower portions of regions 112, 114. Such adjacent exposure might further narrow merged region 115 beyond width w_{A} of line features 110A, 110B and regions 111, 113. The intersection of the middle, intermediate-width portions of overlapping regions 112, 114 provide for a central portion of merged region 115. The width of region 115 may narrow slightly at this central portion due to extra exposure of resist to light, e.g., without the masking of a much-wider overlapping region. The width of region 115 may bulge slightly at this central portion due to the wider widths of these middle portions (relative to the width w_{A} adjacent regions 111, 113). Such narrowing or bulging can advantageously be minimized or prevented by appropriate selection of exposure parameters (e.g., intensity, duration) and widths of features or regions 112, 114.

As shown in FIG. 3A, portion 301 may be implemented in pattern 206 formed on reflective substrate 204 as portions of opaque mask 205, e.g., from light absorber materials. Similarly, portion 302 may be implemented in pattern 206 or pattern 216 also formed on a reflective substrate 204 as portions of opaque mask 205. As discussed, such pattern portions 301, 302 may be provided in the same reticle or in different reticles.

In contexts where different reticles 108, 109 are deployed, as shown, pattern portion 301 is provided adjacent to and orthogonal to an edge 314 of reticle 108 such as at the right edge in the illustrated example. Pattern portion 302 is then provided at an opposite edge 315 (e.g., adjacent to and orthogonal to edge 315) of reticle 109 such as at the left edge as illustrated. Although illustrated with respect to right and left edges 314, 315, top and bottom opposing edges may also be used. It is noted that, in exposure, an overlap 313 of edge 314 and edge 315 is then deployed to provide merged region 315 during processing.

In contexts where the same reticle 107 is used, pattern portion 301 is provided adjacent to and orthogonal to an edge 316 of reticle 107 such as at the right edge in the illustrated example and pattern portion 302 is provided at an opposite edge 317 (e.g., adjacent to and orthogonal to edge 317) of reticle 107 such as the left edge (although top and bottom edges may be used). Notably, pattern portions 301, 302 must be provided on the opposite edges of the same reticle for adjacent fields to see suitable patterns for overlap 313 to provide a resultant line feature 110. Although illustrated with respect to portions of line feature 110, any portions or patterns discussed herein may be deployed on different reticles 108, 109 or the same reticle 107.

FIG. 3B illustrates example portions 301, 302 corresponding to example line feature 110 showing segmented features thereof, in accordance with some embodiments. In FIG. 3B, portion 301 is illustrated as segmented into rectangular region 111 and rectangular features or regions 112A, 112B, 112C, 112D, 112E of region 112. Likewise, portion 302 is illustrated as segmented into rectangular region 113 and rectangular features or regions 114A, 114B, 114C, 114D, 114E of region 114. Such segmentation is provided for the sake of clarity of presentation. Notably, reticle patterns or features may be formed using any lines or shapes inclusive of diagonal or curved lines and the techniques discussed herein may be deployed in such contexts. However, due to simplicity in manufacturing, the size of features, and other constraints, Manhattan routing or patterning is typically deployed.

As discussed, portions 301, 302 have inverse stair-step patterns such that, for portion 301, region 112A adjoins region 111, region 112B adjoins region 112A, region 112C adjoins region 112B, region 112D adjoins region 112C, region 112E adjoins region 112D, and the width of such features increases moving away from region 111. Similarly, for portion 302, region 114A adjoins region 113, region 114B adjoins region 114A, and region 114C adjoins region 114B, region 114D adjoins region 114C, and region 114E adjoins region 114D with the width of such features increasing moving away from region 113. In some embodiments, region 112A may be considered a portion of continuous region 111, e.g., when having the same width w_{A} and sharing a centerline CL₁ with continuous region 111. Likewise, in some embodiments, region 114A may be considered a portion of continuous region 113, e.g., when having the same width w_{A} and sharing a centerline CL₁ with continuous region 113.

Also as shown, across portions 301, 302, each of corresponding regions 112A, 114E, corresponding regions 112B, 114D, corresponding regions 112C, 114C, corresponding regions 112D, 114B, and corresponding regions 112E, 114A have intersections with a width approximately equal to width w_{A} that is shared with regions 111, 113 and line features 110A, 110B. Thereby, line feature 110 has a substantially constant width along a length thereof. (The width of region 115 may narrow slightly at a central portion (e.g., provided by the intersections of overlapping regions 112B, 114D, regions 112C, 114C, and regions 112D, 114B) due to extra exposure of resist to light, e.g., adjacent regions 112C, 114C. The width of region 115 may bulge slightly at this central portion due to the wider widths of regions 112B-112D, 114B-114D. Such narrowing or bulging can advantageously be minimized or prevented by appropriate selection of exposure parameters (e.g., intensity, duration) and widths of features or regions 112, 114.) A constant width across line feature 110 advantageously provides predictable line resistance, consistent design constraints, and other advantages across field boundaries. Notably, regions 112A, 112B, 112C, 112D, 112E provide a pattern in region 112 that is the inverse of the pattern in region 114 provided by regions 114A, 114B, 114C, 114D, 114E and, when overlaid, the patterns provide merged region 315 that is continuous and absent significant narrowing or bulging. As used herein, the term shared overlay region indicates a region that is spanned by both portions 301, 302 (i.e., covered by two reticle patterns and/or exposures).

As shown in FIG. 3B, merged region 115 may have a length L₁ and width w_{A}. The width w_{A} of line 110 may be any suitable width attainable by the lithographic process being applied. For example, width w_{A} may be in the range of 200 to 300 nm, in the range of 150 to 200 nm, in the range of 100 to 150 nm or less. Length L₁ may also be any suitable length with greater lengths providing greater overlap and opportunity for flaring of regions 112, 114 at the cost of wasting space and smaller lengths having the opposite effect. For example, a longer length L₁ of region 115 and correspondingly greater overlap of regions 112, 114 may cost wafer area while allowing for a greater number of regions 112A-112E, 114A-114E, etc., of some minimum length. In some embodiments, the ratio of length L₁ to width w_{A} is about 1. In some embodiments, the ratio of length L₁ to width w_{A} is in the range of 0.5 to 0.8. In some embodiments, the ratio of length L₁ to width w_{A} is in the range of 0.8 to 1.2. In some embodiments, the ratio of length L₁ to width w_{A} is in the range of 1.1 to 1.5. In some embodiments, the ratio of length L₁ to width w_{A} is in the range of 1.5 to 2. Other ratios may be used. It is noted that the line end features in region 112 (or 114) may be evident, without corresponding region 114 (or 112) at regions of a substrate wafer where no stitching occurs, such as at an edge of substrate wafer 103.

FIG. 3C illustrates additional characteristics of example portion 301 corresponding to line feature 110 from a first reticle pattern and corresponding exposure, in accordance with some embodiments. As shown in FIG. 3C, region 112 (including each of regions 112A, 112B, 112C, 112D, 112E) has a shared centerline CL₁ with region 111. Although illustrated with shared centerline CL₁, other patterns may be used. As used herein, the term shared centerline indicates a linear continuous centerline extending through features sharing the centerline. Furthermore, region 112A has the width w_{A}, region 112B has a width w_{B}, region 112C has the width w_{C}, region 112D has the width w_{D}, and region 112E has a width w_{E}, such that width w_{E} is greater than width w_{D}, width w_{D} is greater than width w_{C}, width w_{C} is greater than width w_{B}, and width w_{B} is greater than width w_{A}. As in the illustrated example, regions 112A, 112B, 112C, 112D, 112E may have the same or different lengths. Although illustrated with such characteristics, other features may be used. For example, one, two, three, four, five, or more features may be used and the features may have differing lengths. Furthermore, a constant step down in widths may not be deployed.

FIG. 3C also illustrates additional characteristics of example portion 302 of line 110 from a second exposure and the first reticle pattern or a second reticle pattern. As discussed above, the line end feature of portion 302 has an inverse pattern with respect to that of portion 301. As shown in FIG. 3C, region 114 (including each of regions 114A, 114B, 114C, 114D, 114E) has a shared centerline CL₁ with region 113. Furthermore, regions 114A, 114B, 114C, 114D, 114E have the same widths w_{A}, w_{B}, w_{C}, w_{D}, w_{E} as, and share centerline CL₁ with, regions 112A, 112B, 112C, 112D, 112E of region 112. As in the illustrated example, each of regions 114A, 114B, 114C, 114D, 114E may have the same or different lengths, and they may, but need not, match the lengths of regions 112A, 112B, 112C, 112D, 112E. Other characteristics that provide an inverse of regions 112A, 112B, 112C, 112D, 112E may be used, but regions 112, 114 need not be inverse regions.

FIG. 3D illustrates example portions 301, 302 and line feature 110, in accordance with some embodiments. The embodiment of FIG. 3D is similar to the embodiment of FIG. 3C, for example, having inverse stair-step patterns. Notably, overlapping regions 112, 114 are smaller, and merged region 115 has a correspondingly shorter length L₁. Regions 112A, 114A of width w_{A} are absent, and wide regions 112E, 114E are shorter, having approximately the same length as regions 112B, 112C, 112D. For portion 301, region 112B adjoins region 111, region 112C adjoins region 112B, region 112D adjoins region 112C, region 112E adjoins region 112D, and the width of such features increases moving away from region 111. Similarly, for portion 302, region 114B adjoins region 113, and region 114C adjoins region 114B, region 114D adjoins region 114C, and region 114E adjoins region 114D with the width of such features increasing moving away from region 113. Such pattern portions 301, 302 and merged region 115 may be advantageously be deployed in shorter overlapping regions (e.g., length L₁).

Although FIGS. 3A-3D, etc., describe continuous line features 110 including line features 110A, 110B from regions 111, 113, the exemplary embodiment of FIG. 3D (with a short length L₁) shows how via (or other) features 110 may easily be formed from a similar merged region 115 corresponding to overlapping regions 112, 114 adjacent reticle borders, but without adjacent regions 111, 113. A via (or other) feature 110 need not have a continuous (e.g., line) region spanning exposure fields 105, 106 (and long regions 111, 113 on overlapping reticles), but could be isolated from any other features. A discontinuous via feature 110 may be generated from portions 301, 302 having overlapping regions 112, 114 adjacent reticle borders with no (or minimal) regions 111, 113 extending away from reticle borders.

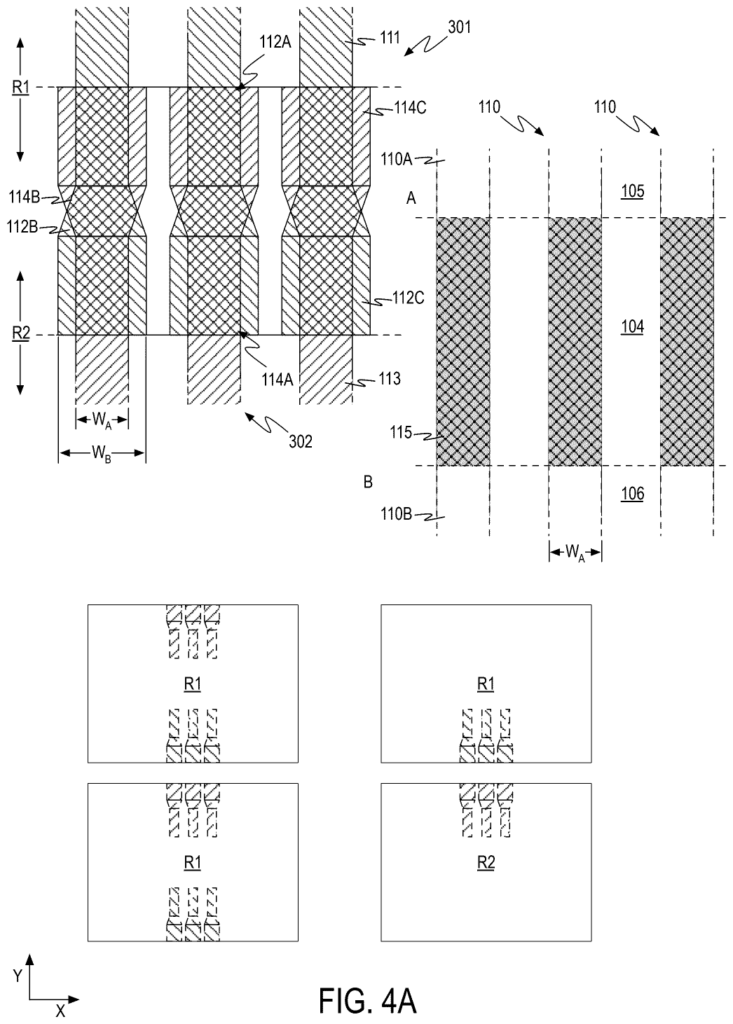

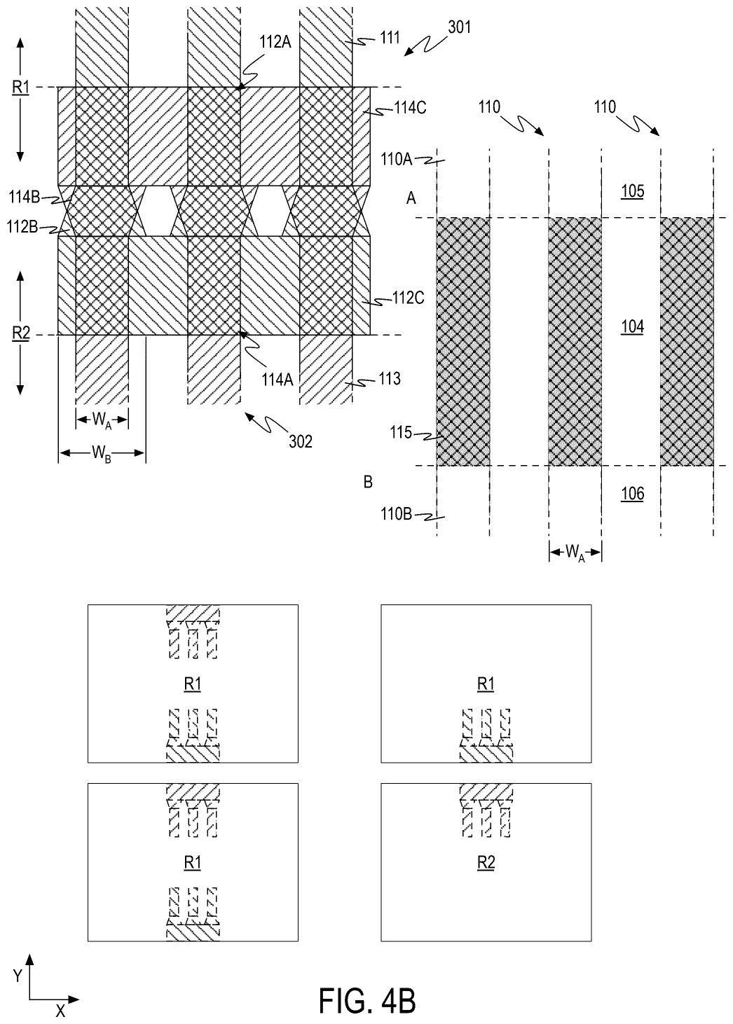

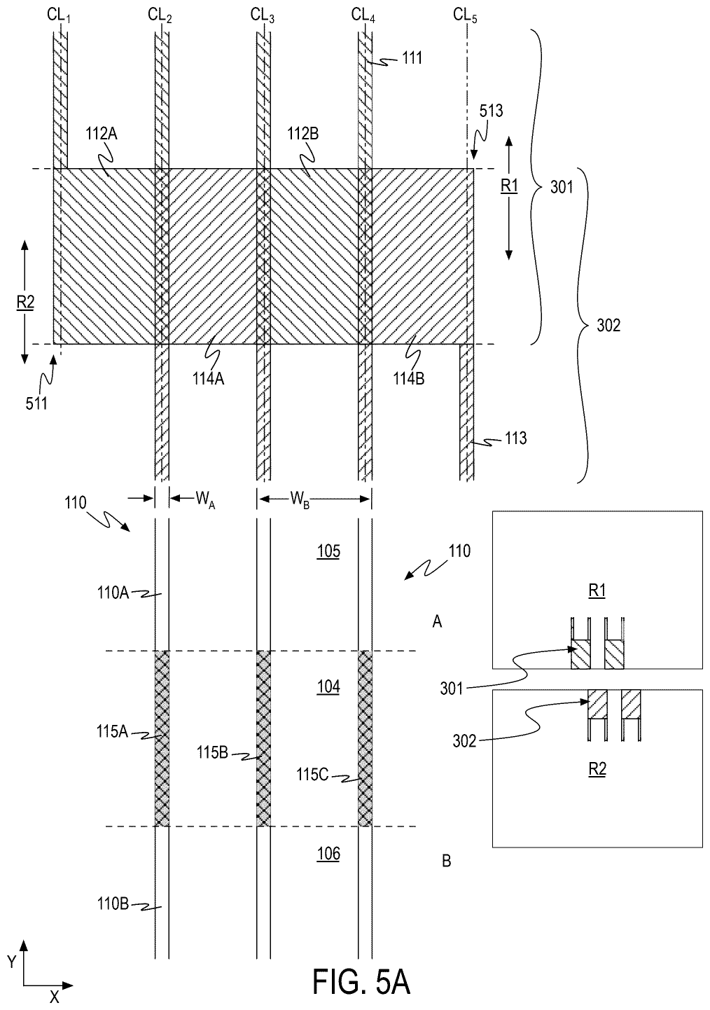

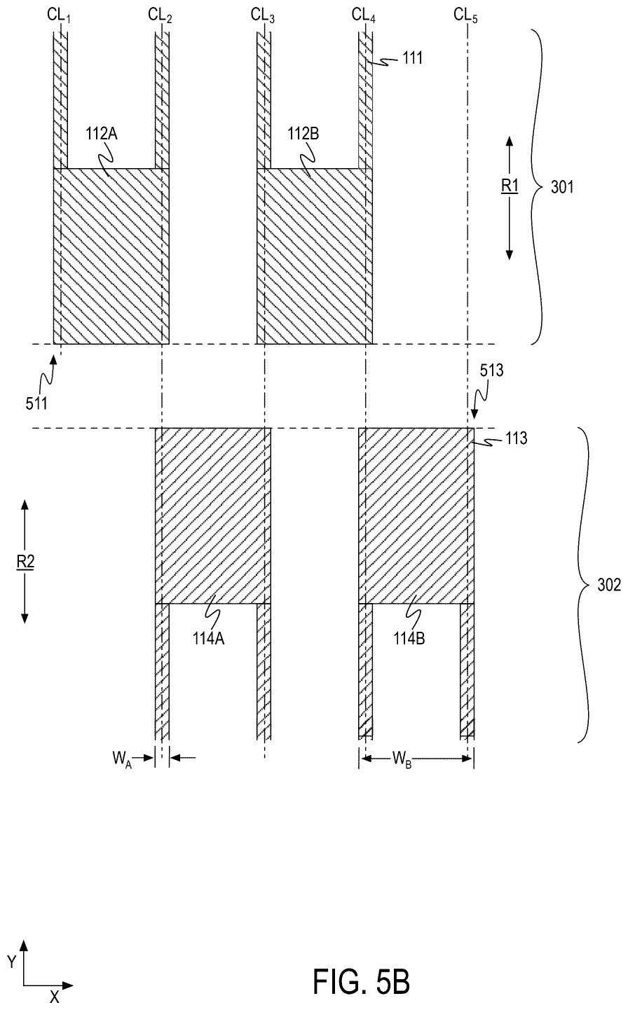

FIGS. 3A-3D illustrate example portions 301, 302 having inverse stair-step patterns in merged region 315. FIGS. 4A, 4B, 5A, and 5B illustrate alternative patterns according to some embodiments. In such illustrations, the implementation within reticles, separate illustration of the portions, illustration of gaps and overlaps, and other characteristics are not repeated for the sake of brevity and clarity of disclosure. It will be evident that any such characteristics discussed with respect to FIGS. 3A-3D may also apply to the patterns discussed with respect to FIGS. 4A, 4B, 5A, and 5B.

FIG. 4A illustrates example line features 110 generated by overlapping first and second portions 301, 302 deploying tapering features or regions 112, 114, in accordance with some embodiments. Line features 110 may be fabricated by overlapping first portion 301 from a first reticle and corresponding exposure and second portion 302 from a second exposure using the first reticle or a second reticle.

First portion 301 includes first continuous feature or region 111 having width w_{A} along a length (in the y-dimension) thereof. As discussed, continuous region 111 is an uninterrupted region in an area defined by width w_{A} and the length of continuous region 111, which may extend in the y-dimension. Adjoining continuous region 111 is a region 112 of first portion 301. As shown, region 112 of first portion 301 has a flaring pattern, widening from width w_{A} to width w_{B}. Second portion 302 of line feature 110 includes continuous region 113 having width w_{A} along a length thereof. Continuous region 113 is adjoined by region 114 of second portion 302. Region 114 of second portion 302 has a flaring pattern, widening from width w_{A} to width w_{B}, but in an opposite direction, in an inverse or complementary pattern relative to the pattern of region 112. The pattern of region 114 and the pattern of region 112 overlap to provide merged region 115.

Region 112 of portion 301 includes features or regions 112A, 112B, 112C. Region 112A adjoins continuous region 111, region 112B adjoins region 112A, and region 112C adjoins region 112B. In some embodiments, region 112A is considered a portion of continuous region 111 (having a same width w_{A} and sharing a centerline). Region 112C has a width w_{B} and shares the same centerline. Region 112B tapers outward from width w_{A} at continuous region 111 to width w_{B} (greater than width w_{A}). Inverse portions 301, 302 are reflections of each other. Region 114 of portion 302 includes features or regions 114A, 114B, 114C. Region 114A adjoins continuous region 113, region 114B adjoins region 114A, and region 114C adjoins region 114B. In some embodiments, region 114A is considered a portion of continuous region 111 (having a same width w_{A} and sharing a centerline). Region 114C has a width w_{B} and shares the same centerline. Region 114B tapers outward from width w_{A} at continuous region 111 to width w_{B} (greater than width w_{A}).

FIG. 4B illustrates example pattern portions 301, 302 having shared regions 112C, 114C adjoining multiple individual features or regions 112B, in accordance with some embodiments. Inverse portions 301, 302 are similar to those described at FIG. 4A. Notably, a single region 112C is shared by multiple regions 111, 112A, 112B, and a single region 114C is shared by multiple regions 113, 114A, 114B. Region 112A adjoins continuous region 111, region 112B adjoins region 112A, and a larger region 112C adjoins region 112B. Region 112B tapers outward from width w_{A} at continuous region 111 to width w_{B} (greater than width w_{A}) at region 112C. Region 112A adjoins continuous region 111, region 112B adjoins region 112A, and a larger region 112C adjoins region 112B. Region 112B tapers outward from width w_{A} at continuous region 111 to width w_{B} (greater than width w_{A}) at region 112C.

FIG. 5A illustrates example line features 110 generated by overlaying first and second pattern portions 301, 302 having shared regions 112, 114 adjoining multiple individual continuous regions 111, in accordance with some embodiments. Line features 110 may be fabricated by overlapping a first portion 301 from a first reticle and corresponding exposure and a second portion 302 from a second exposure using the first reticle or a second reticle.

First portion 301 includes at least the four shown continuous features or regions 111 having width w_{A} along a length (in the y-dimension) thereof. Pairs of continuous regions 111 are adjoined by a shared region 112 of first portion 301 such that the shared region 112 of first portion 301 shares an outer edge 511 with each continuous region 111 and overlaps the center axis of each continuous region 111. Second portion 302 of line feature 110 includes at least the four shown continuous regions 113 having width w_{A} along a length thereof. Pairs of continuous regions 113 are adjoined by shared region 114 of second portion 302, and shared region 114 shares an outer edge 513 with each continuous region 113 and overlaps the center axis of each continuous region 113. Regions 114 of second portions 302 and regions 112 overlap to form or provide merged region 115.

Merged regions 115 share center lines or center axes with continuous regions 111, 113, but not with regions 112, 114. Regions 112, 114 overlap or intersect to provide a corresponding merged region 115, but are not centered along the same axes. Each region 112 is a single feature or region 112 adjoining continuous region 111, and the single feature or region 112 shares an edge 511 of region 111 and has a width w_{B} greater than width w_{A}. Each region 114 is a single feature or region 114 adjoining continuous region 113, and the single feature or region 114 shares an edge 513 of region 113 and has a width w_{B} greater than width w_{A}.

For example, region 112A shares edges 511 with, and overlaps centerlines CL₁, CL₂ of, corresponding continuous regions 111. Region 112B shares edges 511 with, and overlaps centerlines CL₃, CL₄ of, corresponding continuous regions 111. Region 114A shares edges 513 with, and overlaps centerlines CL₂, CL₃ of, corresponding continuous regions 113. Region 114B shares edges 513 with, and overlaps centerlines CL₄, CL₅ of, corresponding continuous regions 113. Regions 112A, 114A overlap such that their intersection provides for merged region 115A with width w_{A}. Regions 112B, 114A overlap such that their intersection provides for merged region 115B with width w_{A}. Regions 112B, 114B overlap such that their intersection provides for merged region 115C with width w_{A}.

FIG. 5B illustrates example pattern portions 301, 302 generated by overlaying first and second portions 301, 302 having shared regions 112, 114 adjoining multiple individual continuous regions 111, in accordance with some embodiments. In FIG. 5B, portions 301, 302 of FIG. 5A are shown offset rather than overlapping, e.g., for illustrative purposes. Regions 112, 114 span and overlap pairs of centerlines of continuous regions 111, 113. Regions 112, 114 have widths w_{B}, and continuous regions 111, 113 have widths w_{A}. Regions 112 (or 114) share edges 511 (or 513) with continuous regions 111 (or 113).

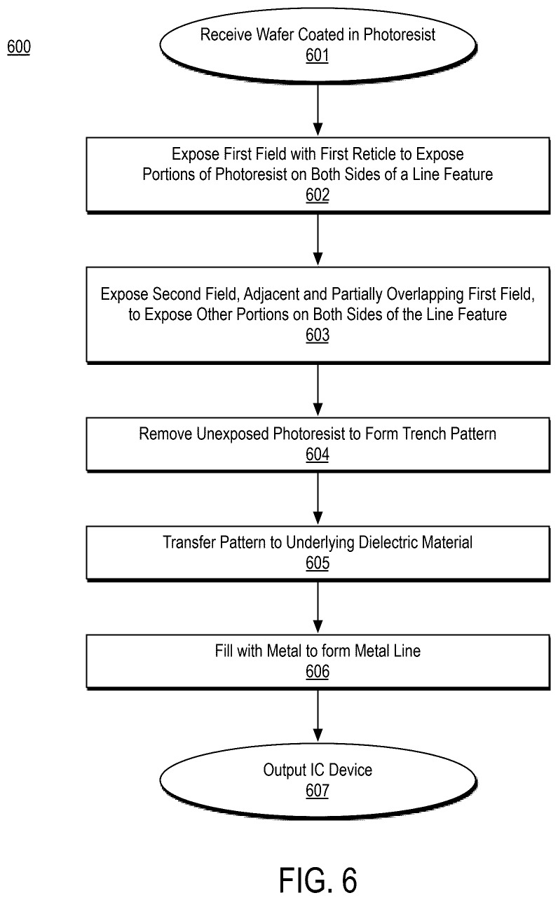

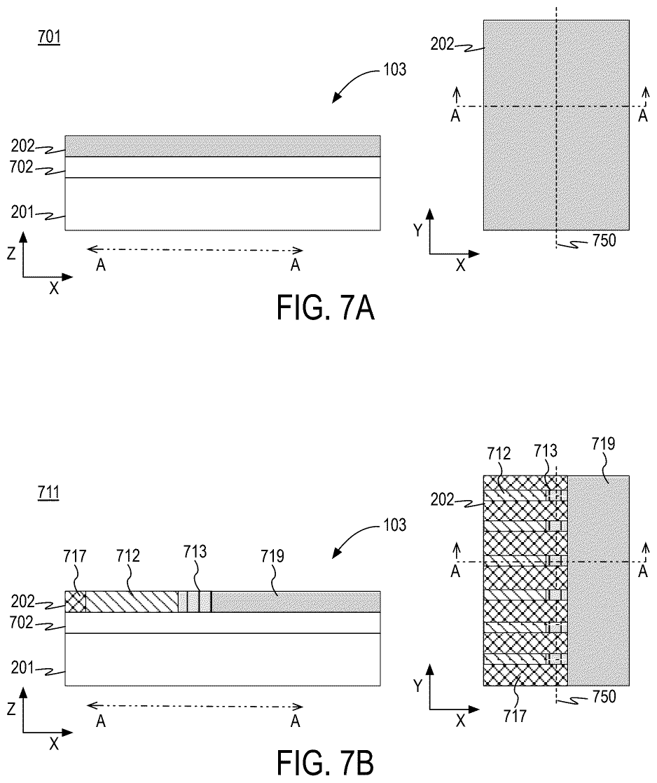

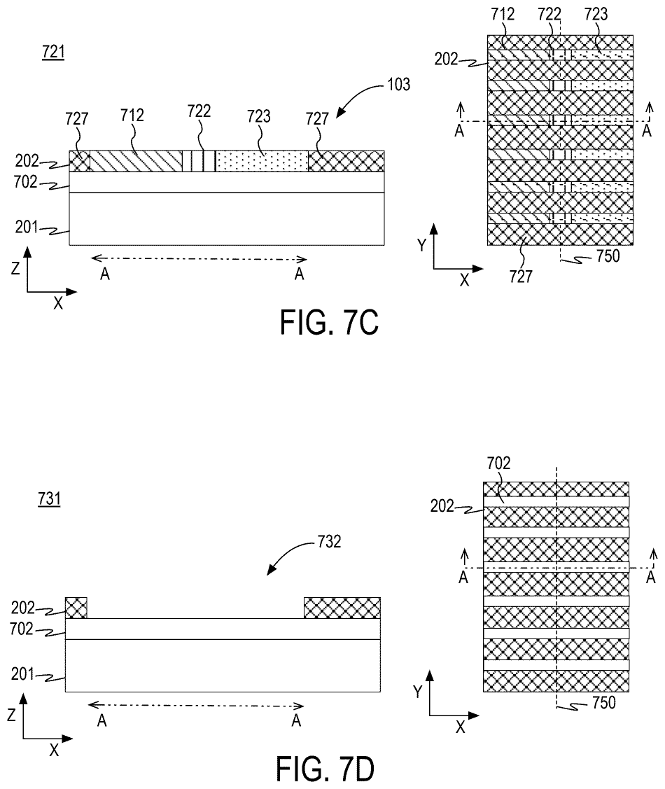

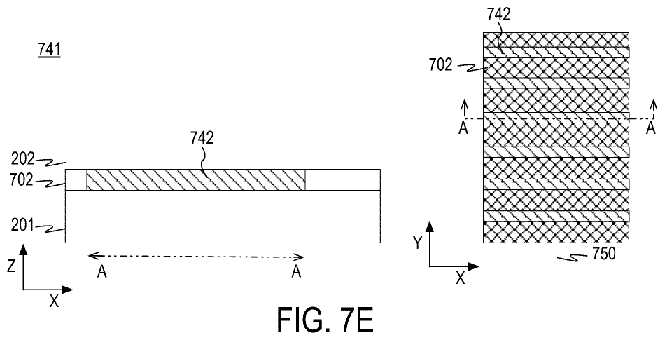

FIG. 6 is a flow diagram illustrating an example process 600 for fabricating an integrated circuit device, in accordance with some embodiments. For example, process 600 may be implemented to fabricate device structures illustrated in FIGS. 7A-7E.

FIGS. 7A, 7B, 7C, 7D, and 7E are views of example integrated circuit device structures as particular fabrication operations are performed, in accordance with some embodiments.

With reference to FIG. 6, process 600 begins at operation 601, where a wafer coated in photoresist is received for processing. The wafer may include any suitable substrate material. For example, the substrate may include a semiconductor material such as monocrystalline silicon (Si), germanium (Ge), silicon germanium (SiGe), a III-V materials-based material (e.g., gallium arsenide (GaAs)), a silicon carbide (SiC), a sapphire (Al₂O₃), or any combination thereof. The wafer may further include, in, on, and/or over the substrate, a device layer and one or more metallization layers. The device layer may include transistors, memory devices, capacitors, resistors, optoelectronic devices, switches, or any other active or passive electronic devices, or portions thereof. The metallization layer(s) may include via layers and metal line layers to interconnect and provide access to the devices. The wafer is coated with a photoresist layer for patterning operations. The photoresist layer may include any suitable photoresist, such as a negative tone photoresist material.

FIG. 7A illustrates a cross-sectional and top-down views of an integrated circuit device structure 701 after the formation of photoresist layer 202 on a dielectric layer 702 over substrate 201. In FIG. 7A and FIGS. 7B, 7C, 7D, and 7E, the left side provides a cross-sectional view of a portion of integrated circuit device structure 701 and the right side provides a top down view of portion A-A across a field boundary 750. As discussed, substrate 201 may include any material(s) such as monocrystalline silicon, germanium, silicon germanium, a III-V materials-based material (e.g., gallium arsenide), a silicon carbide, a sapphire, or the like. A device layer of substrate 201 may include any devices such as transistors, memory devices, capacitors, resistors, optoelectronic devices, switches, or any other active or passive electronic devices. Such devices are fabricated using known techniques such as lithography, etch, deposition, implant, etc. Dielectric layer 702 is over substrate 201. For example, substrate 201 may include metallization layers at a top thereof that are to be contacted by reticle stitched metal lines formed in dielectric layer 702 using single damascene or dual damascene techniques.

Returning to FIG. 6, processing continues at operation 602, where a first field of the substrate and photoresist layer is exposed using a first reticle such that first and second portions on either side of a line feature are exposed while not exposing a third portion of the photoresist layer between the first and second portions. The unexposed third portion includes a continuous first region of a line feature and a second region adjoining the first region. The first reticle and first field may include any portions discussed herein, such as any of portions 301, 302. Notably, the unexposed region with unexposed features includes portions or features or regions as discussed herein. The region may have a stair-step pattern, a flared pattern, or the like.

FIG. 7B illustrates an integrated circuit device structure 711 similar to integrated circuit device structure 701 after patterning a first portion of a line feature. As shown, after the first exposure, regions 712, 713 of photoresist layer 202, having been masked, have not been exposed and region 717 has been exposed. No portion of region 719 has yet been exposed. Region 713 may match any region of any line feature portion discussed herein such as any of regions 112, 114. As shown, regions 713 straddle or extend across field boundary 750.

Returning to FIG. 6, processing continues at operation 603, where a second field, adjacent and partially overlapping the first field exposed in operation 602, of the substrate is exposed using the first reticle or a second reticle such that fourth and fifth portions of the photoresist layer are exposed on either side of an unexposed sixth portion of the photoresist layer (between the fourth and fifth portions). The unexposed sixth portion includes a continuous third region of the line feature and a fourth region adjoining the third region. The fourth region partially overlaps (i.e., intersects) the second region of the first exposure field at operation 602 to provide a merged region between the continuous first and third regions, which together form or provide a line feature. The unexposed third and sixth portions partially overlap (i.e., intersect) and include these first through fourth regions. The first or second reticle and second field may include any portions discussed herein such as the inverse ones of portions 301, 302 as patterned at operation 602.

FIG. 7C illustrates an integrated circuit device structure 721 similar to integrated circuit device structure 711 after patterning a second portion of the line feature. As shown, the second exposure fully exposes region 727 of photoresist layer 202 and completes the patterning of merged region 722 of photoresist layer 202. The second pattern patterned to complete patterning of merged region 722 may be the matching inverse or complement pattern of any region of any line feature portion discussed herein such as any of regions 112, 114 as discussed herein. As shown, merged regions 722 straddle or extend across field boundary 750. Although illustrated with different patterns for the sake of clarity of presentation, unexposed region 712, unexposed merged region 722, and unexposed region 723 are now all still fully soluble photoresist substantially sharing the same properties. Fully exposed region 727 has been polymerized and is insoluble.

Returning to FIG. 6, processing continues at operation 604, where the photoresist is developed to form trench patterns in the photoresist layer. The photoresist may be developed using any suitable technique or techniques that remove the unexposed portions of the photoresist and leave exposed portions of the photoresist. As discussed, the exposure of photoresist regions hardens or polymerizes the resist polymer making it insoluble in a developer solution.

FIG. 7D illustrates an integrated circuit device structure 731 similar to integrated circuit device structure 721 after developing photoresist layer 202. As shown, after develop, photoresist layer 202 includes a trench pattern 732 in photoresist layer 202. Trench pattern 732 may include any pattern inclusive of unexposed region 712, unexposed merged region 722, and unexposed region 723. Deployment of line end patterns discussed herein facilitates improved patterning of photoresist layer 202.

Returning to FIG. 6, processing continues at operation 605, where the pattern in the photoresist layer is transferred to an underlying dielectric material. The pattern in the photoresist layer may be transferred to the underlying dielectric material using any suitable technique or techniques such as etch techniques. Although illustrated herein with respect to transfer of the pattern in the photoresist layer to a dielectric material for the formation of an eventual metal line, the pattern in the photoresist layer may be used in any suitable fabrication processing.

Processing continues at operation 606, where the pattern in the dielectric material is filled with a metal or metals to form a metal signal, power, etc., line of an integrated circuit device. The metal line may be formed using any suitable technique or techniques such as application of a liner material (e.g., titanium nitride, tantalum nitride, or the like), followed by bulk metal fill (e.g., copper fill), which may be followed by planarization techniques. Other metal fill materials and/or processing may be used.

Processing continues at operation 607, where an integrated circuit device including reticle stitched metal lines is output. For example, a die including multiple fields connected by reticle stitched metal lines may be segmented from a remainder of the substrate (i.e., substrate wafer), packaged, and so on, and eventually included in an electronic device.

FIG. 7E illustrates an integrated circuit device structure 741 similar to integrated circuit device structure 721 after the removal of photoresist layer 202 (e.g., using ash processing) and formation of metal line 742 in a trench of dielectric. As shown, metal line 742 (and optional liner, not shown) are formed in a trench of dielectric layer 702. Metal line 742 may be formed using any suitable technique or techniques. In some embodiments, dielectric layer 702 is patterned resultant trench pattern 732 (i.e., using etch techniques) to form a trench in trench pattern 732 and forming metal line 742 in the trench.

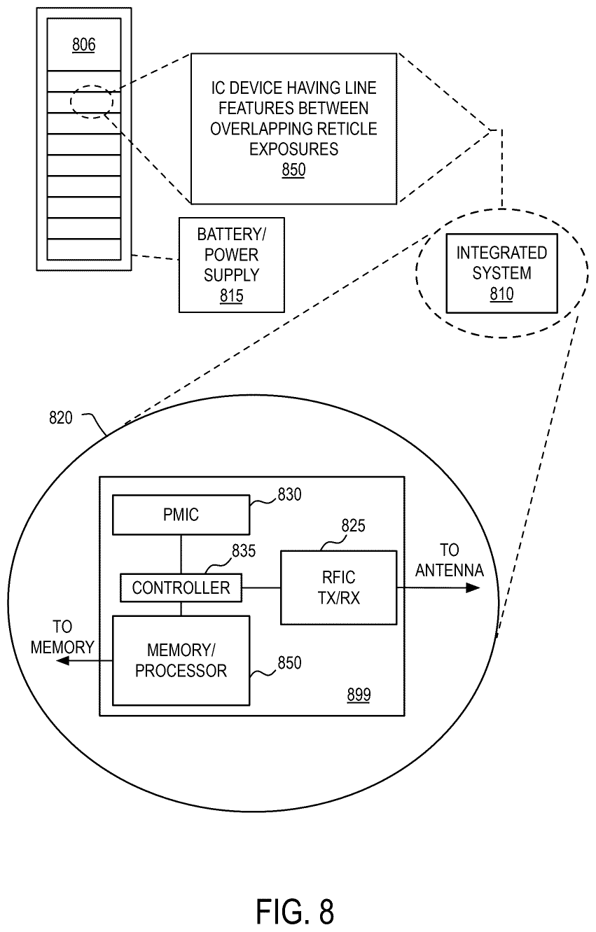

FIG. 8 illustrates a diagram of an example data server machine 806 employing an IC device having line features between overlapping reticle exposures, in accordance with some embodiments. Server machine 806 may be any commercial server, for example, including any number of high-performance computing platforms disposed within a rack and networked together for electronic data processing, which in the exemplary embodiment includes one or more devices 850 with line features between overlapping reticle exposures.

Also as shown, server machine 806 includes a battery and/or power supply 815 to provide power to devices 850, and to provide, in some embodiments, power delivery functions such as power regulation. Devices 850 may be deployed as part of a package-level integrated system 810. Integrated system 810 is further illustrated in the expanded view 820. In the exemplary embodiment, devices 850 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 850 is a microprocessor including a static RAM (SRAM) cache memory. As shown, device 850 may be an IC device having line features between overlapping reticle exposures, as discussed herein. Device 850 may be further coupled to (e.g., communicatively coupled to) a board, an interposer, or a substrate 899 along with, one or more of a power management IC (PMIC) 830, RF (wireless) IC (RFIC) 825 including a wideband RF (wireless) transmitter and/or receiver (TX/RX) (e.g., including a digital baseband and an analog front end module further includes a power amplifier on a transmit path and a low noise amplifier on a receive path), and a controller 835 thereof. In some embodiments, RFIC 825, PMIC 830, controller 835, and device 850 include overlapping reticle exposures and line features coupling between the exposures.

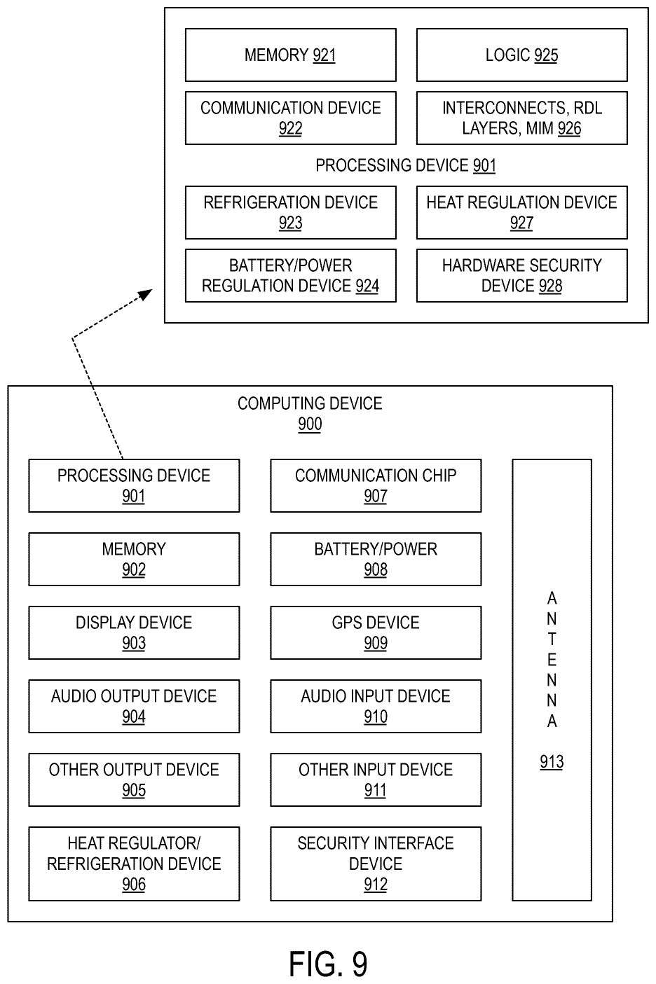

FIG. 9 is a block diagram of an example computing device 900, in accordance with some embodiments. For example, one or more components of computing device 900 may include any of the devices or structures discussed herein. A number of components are illustrated in FIG. 9 as being included in computing device 900, but any one or more of these components may be omitted or duplicated, as suitable for the application. In some embodiments, some or all of the components included in computing device 900 may be attached to one or more printed circuit boards (e.g., a motherboard). In some embodiments, various ones of these components may be fabricated onto a single system-on-a-chip (SoC) die. Additionally, in various embodiments, computing device 900 may not include one or more of the components illustrated in FIG. 9, but computing device 900 may include interface circuitry for coupling to the one or more components. For example, computing device 900 may not include a display device 903, but may include display device interface circuitry (e.g., a connector and driver circuitry) to which display device 903 may be coupled. In another set of examples, computing device 900 may not include an audio output device 904, other output device 905, global positioning system (GPS) device 909, audio input device 910, or other input device 911, but may include audio output device interface circuitry, other output device interface circuitry, GPS device interface circuitry, audio input device interface circuitry, audio input device interface circuitry, to which audio output device 904, other output device 905, GPS device 909, audio input device 910, or other input device 911 may be coupled.

Computing device 900 may include a processing device 901 (e.g., one or more processing devices). As used herein, the term “processing device” or “processor” indicates a device that processes electronic data from registers and/or memory to transform that electronic data into other electronic data that may be stored in registers and/or memory. Processing device 901 may include a memory 921, a communication device 922, a refrigeration device 923, a battery/power regulation device 924, logic 925, interconnects 926 (i.e., optionally including redistribution layers (RDL) or metal-insulator-metal (MIM) devices), a heat regulation device 927, and a hardware security device 928.

Processing device 901 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 900 may include a memory 902, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 902 includes memory that shares a die with processing device 901. This memory may be used as cache memory and may include embedded dynamic random-access memory (eDRAM) or spin transfer torque magnetic random-access memory (STT-MRAM).

Computing device 900 may include a heat regulation/refrigeration device 906. Heat regulation/refrigeration device 906 may maintain processing device 901 (and/or other components of computing device 900) at a predetermined low temperature during operation.

In some embodiments, computing device 900 may include a communication chip 907 (e.g., one or more communication chips). For example, the communication chip 907 may be configured for managing wireless communications for the transfer of data to and from computing device 900. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 907 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 907 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 907 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 907 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 907 may operate in accordance with other wireless protocols in other embodiments. Computing device 900 may include an antenna 913 to facilitate wireless communications and/or to receive other wireless communications (such as AM or FM radio transmissions).

In some embodiments, communication chip 907 may manage wired communications, such as electrical, optical, or any other suitable communication protocols (e.g., the Ethernet). As noted above, communication chip 907 may include multiple communication chips. For instance, a first communication chip 907 may be dedicated to shorter-range wireless communications such as Wi-Fi or Bluetooth, and a second communication chip 907 may be dedicated to longer-range wireless communications such as GPS, EDGE, GPRS, CDMA, WiMAX, LTE, EV-DO, or others. In some embodiments, a first communication chip 907 may be dedicated to wireless communications, and a second communication chip 907 may be dedicated to wired communications.

Computing device 900 may include battery/power circuitry 908. Battery/power circuitry 908 may include one or more energy storage devices (e.g., batteries or capacitors) and/or circuitry for coupling components of computing device 900 to an energy source separate from computing device 900 (e.g., AC line power).

Computing device 900 may include a display device 903 (or corresponding interface circuitry, as discussed above). Display device 903 may include any visual indicators, such as a heads-up display, a computer monitor, a projector, a touchscreen display, a liquid crystal display (LCD), a light-emitting diode display, or a flat panel display, for example.

Computing device 900 may include an audio output device 904 (or corresponding interface circuitry, as discussed above). Audio output device 904 may include any device that generates an audible indicator, such as speakers, headsets, or earbuds, for example.

Computing device 900 may include an audio input device 910 (or corresponding interface circuitry, as discussed above). Audio input device 910 may include any device that generates a signal representative of a sound, such as microphones, microphone arrays, or digital instruments (e.g., instruments having a musical instrument digital interface (MIDI) output).

Computing device 900 may include a GPS device 909 (or corresponding interface circuitry, as discussed above). GPS device 909 may be in communication with a satellite-based system and may receive a location of computing device 900, as known in the art.

Computing device 900 may include other output device 905 (or corresponding interface circuitry, as discussed above). Examples of the other output device 905 may include an audio codec, a video codec, a printer, a wired or wireless transmitter for providing information to other devices, or an additional storage device.

Computing device 900 may include other input device 911 (or corresponding interface circuitry, as discussed above). Examples of the other input device 911 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 900 may include a security interface device 912. Security interface device 912 may include any device that provides security measures for computing device 900 such as intrusion detection, biometric validation, security encode or decode, access list management, malware detection, or spyware detection.

Computing device 900, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1A-9. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, one or more lithographic reticles includes a first pattern on a first lithographic reticle, the first pattern including a continuous first region of a line feature having a first width and a second region of the first pattern adjoining the first region, the second region including one or more first pattern features, and a second pattern on the first or a second lithographic reticle, the second pattern including a continuous third region of the line feature having the first width and a fourth region of the second pattern adjoining the third region, wherein, when overlaid, an intersection of the second and fourth regions provide a substantially continuous merged region of the line feature.

In one or more second embodiments, further to the first embodiments, each of the first pattern features has a different width greater than or equal to the first width, and the first region and each of the first pattern features include a shared center axis.

In one or more third embodiments, further to the first or second embodiments, the first pattern features include a first feature adjoining the first region, a second feature adjoining the first feature, and a third feature adjoining the second feature, the first feature having a second width less than a third width of the second feature, and the third width less than a fourth width of the third feature.

In one or more fourth embodiments, further to the first through third embodiments, the first pattern features include a first feature tapering outward to a second width greater than the first width.

In one or more fifth embodiments, further to the first through fourth embodiments, the first pattern features include a first feature adjoining the first region, and a second feature adjoining the first feature but not the first region, the first feature having a second width less than a third width of the second feature.

In one or more sixth embodiments, further to the first through fifth embodiments, the first pattern features include a single feature adjoining the first region, the single feature sharing an edge of the first region and having a width greater than the first width.

In one or more seventh embodiments, further to the first through sixth embodiments, the line feature is a first line feature, and the merged region is a first merged region, also including a second line feature including continuous fifth and sixth regions and a substantially continuous second merged region between the fifth and sixth regions, wherein the first pattern includes the fifth region, the second pattern includes the sixth region, and the second region overlaps the second merged region.

In one or more eighth embodiments, further to the first through seventh embodiments, the first lithographic reticle includes a substantially opaque mask on a reflective substrate, and the first and second regions of the first pattern are defined on the substrate by one or more absorber structures of the mask.

In one or more ninth embodiments, further to the first through eighth embodiments, the second pattern is on the first lithographic reticle, the first and second regions are adjacent a first edge of the first lithographic reticle, the third and fourth regions are adjacent a second edge of the first lithographic reticle opposite the first edge, the first region is aligned with the third region on a shared center axis, and the second and fourth regions overlap the shared center axis of the first and third regions.

In one or more tenth embodiments, an apparatus includes a reflective substrate, including a first edge and a second edge opposite the first edge, and a substantially opaque mask on the reflective substrate, the opaque mask including a plurality of absorber structures that define a pattern in the reflective substrate, the pattern including first and second portions, wherein the first portion is adjacent and orthogonal to the first edge, the first portion includes a continuous first region of a line feature and a second region of the pattern adjoining the first region, the second region is adjacent the first edge and includes a first edge feature, the second portion is adjacent and orthogonal to the second edge,

In one or more eleventh embodiments, further to the tenth embodiments, the second region includes a plurality of third features sharing the center axis with the first region.

In one or more twelfth embodiments, further to the tenth or eleventh embodiments, the plurality of third features include a plurality of widths, and the widths of the third features increase moving away from the first region.

In one or more thirteenth embodiments, further to the tenth through twelfth embodiments, the second region includes one or more third features having a shared edge with the first region.

In one or more fourteenth embodiments, further to the tenth through thirteenth embodiments, the second region includes one or more third features having a first width greater than a second width of the first region.

In one or more fifteenth embodiments, further to the tenth through fourteenth embodiments, the line feature is a first line feature, and the center axis is a first center axis, also including a second line feature including a second center axis, wherein the second region overlaps the second center axis.

In one or more sixteenth embodiments, a method includes exposing a first field of a photoresist layer over a substrate wafer using a first reticle, said exposing the first field to expose first and second portions of the photoresist layer, while not exposing a third portion of the photoresist layer between the first and second portions, the unexposed third portion including a continuous first region of a line feature and a second region adjoining the first region, exposing a second field of the photoresist layer partially overlapping the first field using the first reticle or a second reticle, said exposing the second field to expose fourth and fifth portions of the photoresist layer, while not exposing a sixth portion of the photoresist layer between the fourth and fifth portions, the unexposed sixth portion including a continuous third region of the line feature and a fourth region adjoining the third region, and developing the photoresist layer to form a resultant trench pattern corresponding to the line feature, the line feature including the first and third regions and an intersection of the second and fourth regions.

In one or more seventeenth embodiments, further to the sixteenth embodiments, the unexposed second region includes an unexposed first feature having a first width adjoining the unexposed continuous first region, an unexposed second feature having a second width adjoining the first unexposed feature, and a third unexposed feature having a third width adjoining the second unexposed feature, wherein the unexposed continuous first region and each of the first, second, and third unexposed features include a shared center axis edge, the third width is greater than the second width, and the second width is greater than the first width.

In one or more eighteenth embodiments, further to the sixteenth or seventeenth embodiments, the unexposed second region includes an unexposed first feature having a first width adjoining the unexposed continuous first region and an unexposed second feature having a second width adjoining the first feature but not the unexposed continuous first region, wherein the second width is greater than the first width.

In one or more nineteenth embodiments, further to the sixteenth through eighteenth embodiments, the unexposed continuous first region, first feature, and second feature are aligned along a shared center axis of the unexposed continuous first region, the first feature, and the second feature.

In one or more twentieth embodiments, further to the sixteenth through nineteenth embodiments, the method also includes patterning a dielectric layer using the resultant trench pattern to form a trench in the dielectric layer, and forming a metal line in the trench.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. One or more lithographic reticles, comprising:
a first pattern on a first lithographic reticle, the first pattern comprising a continuous first region of a line feature having a first width and a second region of the first pattern adjoining the first region, the second region comprising one or more first pattern features; and
a second pattern on the first or a second lithographic reticle, the second pattern comprising a continuous third region of the line feature having the first width and a fourth region of the second pattern adjoining the third region, wherein, when overlaid, an intersection of the second and fourth regions provide a substantially continuous merged region of the line feature.

2. The one or more lithographic reticles of claim 1, wherein each of the first pattern features has a different width greater than or equal to the first width, and the first region and each of the first pattern features comprise a shared center axis.

3. The one or more lithographic reticles of claim 2, wherein the first pattern features comprise a first feature adjoining the first region, a second feature adjoining the first feature, and a third feature adjoining the second feature, the first feature having a second width less than a third width of the second feature, and the third width less than a fourth width of the third feature.

4. The one or more lithographic reticles of claim 1, wherein the first pattern features comprise a first feature tapering outward to a second width greater than the first width.

5. The one or more lithographic reticles of claim 1, wherein the first pattern features comprise a first feature adjoining the first region, and a second feature adjoining the first feature but not the first region, the first feature having a second width less than a third width of the second feature.

6. The one or more lithographic reticles of claim 1, wherein the first pattern features comprise a single feature adjoining the first region, the single feature sharing an edge of the first region and having a width greater than the first width.

7. The one or more lithographic reticles of claim 1, wherein the line feature is a first line feature, and the merged region is a first merged region, further comprising a second line feature comprising continuous fifth and sixth regions and a substantially continuous second merged region between the fifth and sixth regions, wherein:
the first pattern comprises the fifth region;
the second pattern comprises the sixth region; and
the second region overlaps the second merged region.

8. The one or more lithographic reticles of claim 1, wherein the first lithographic reticle comprises a substantially opaque mask on a reflective substrate, and the first and second regions of the first pattern are defined on the substrate by one or more absorber structures of the mask.

9. The one or more lithographic reticles of claim 1, wherein:
the second pattern is on the first lithographic reticle;
the first and second regions are adjacent a first edge of the first lithographic reticle;
the third and fourth regions are adjacent a second edge of the first lithographic reticle opposite the first edge;
the first region is aligned with the third region on a shared center axis; and
the second and fourth regions overlap the shared center axis of the first and third regions.

10. An apparatus, comprising:
a reflective substrate, comprising a first edge and a second edge opposite the first edge; and
a substantially opaque mask on the reflective substrate, the opaque mask comprising a plurality of absorber structures that define a pattern in the reflective substrate, the pattern comprising first and second portions, wherein:
the first portion is adjacent and orthogonal to the first edge;
the first portion comprises a continuous first region of a line feature and a second region of the pattern adjoining the first region;
the second region is adjacent the first edge and comprises a first edge feature;
the second portion is adjacent and orthogonal to the second edge;
the second portion comprises a continuous third region of the line feature and a fourth region of the pattern adjoining the third region; and
the fourth region is adjacent to the second edge and comprises a second edge feature, the first and second edge features overlapping a center axis of the first region.

11. The apparatus of claim 10, wherein the second region comprises a plurality of third features sharing the center axis with the first region.

12. The apparatus of claim 11, wherein the plurality of third features comprise a plurality of widths, and the widths of the third features increase moving away from the first region.

13. The apparatus of claim 10, wherein the second region comprises one or more third features having a shared edge with the first region.

14. The apparatus of claim 10, wherein the second region comprises one or more third features having a first width greater than a second width of the first region.

15. The apparatus of claim 14, wherein the line feature is a first line feature, and the center axis is a first center axis, further comprising a second line feature comprising a second center axis, wherein the second region overlaps the second center axis.

16. A method, comprising:
exposing a first field of a photoresist layer over a substrate wafer using a first reticle, said exposing the first field to expose first and second portions of the photoresist layer, while not exposing a third portion of the photoresist layer between the first and second portions, the unexposed third portion comprising a continuous first region of a line feature and a second region adjoining the first region;
exposing a second field of the photoresist layer partially overlapping the first field using the first reticle or a second reticle, said exposing the second field to expose fourth and fifth portions of the photoresist layer, while not exposing a sixth portion of the photoresist layer between the fourth and fifth portions, the unexposed sixth portion comprising a continuous third region of the line feature and a fourth region adjoining the third region; and
developing the photoresist layer to form a resultant trench pattern corresponding to the line feature, the line feature comprising the first and third regions and an intersection of the second and fourth regions.

17. The method of claim 16, wherein the unexposed second region comprises an unexposed first feature having a first width adjoining the unexposed continuous first region, an unexposed second feature having a second width adjoining the first unexposed feature, and a third unexposed feature having a third width adjoining the second unexposed feature, wherein the unexposed continuous first region and each of the first, second, and third unexposed features comprise a shared center axis edge, the third width is greater than the second width, and the second width is greater than the first width.

18. The method of claim 16, wherein the unexposed second region comprises an unexposed first feature having a first width adjoining the unexposed continuous first region and an unexposed second feature having a second width adjoining the first feature but not the unexposed continuous first region, wherein the second width is greater than the first width.

19. The method of claim 18, wherein the unexposed continuous first region, first feature, and second feature are aligned along a shared center axis of the unexposed continuous first region, the first feature, and the second feature.

20. The method of claim 16, further comprising:
patterning a dielectric layer using the resultant trench pattern to form a trench in the dielectric layer; and
forming a metal line in the trench.
